(19) United States
(12) Patent Application Publication
(10) Pub. No.: US 2013/0181339 A1
(43) Pub. Date: Jul. 18, 2013

(54) MULTI-CHIP SELF-ALIGNMENT ASSEMBLY WHICH CAN BE USED WITH FLIP-CHIP BONDING

(71) Applicants: Wenjun Fan, Milpitas, CA (US); Ruolin Li, Milpitas, CA (US)

(72) Inventors: Wenjun Fan, Milpitas, CA (US); Ruolin Li, Milpitas, CA (US)

(73) Assignee: Mars Technology

(21) Appl. No.: 13/349,491

(22) Filed: Jan. 12, 2012

(51) Int. Cl. H01L 23/498; H01L 21/50

(52) U.S. Cl. 257/737; 438/108; 257/797; 257/E21.499; 257/E23.068

(57) ABSTRACT

A method and structure for mechanical self-alignment of semiconductor device features, for example multi-chip module features. Alignment of the features can be performed using mechanical alignment grooves within a layer of a first device and mechanical alignment pedestals of a second device. The alignment accuracy is limited by the patterning resolution of the semiconductor processing, which is in sub-micron scale. Flip-chip bonding can be used as the bonding process between chips to increase the alignment precision.

### FIELD OF THE EMBODIMENTS

The present teachings relate to the field of alignment methods and structures for electrical and optoelectronic component assemblies such as semiconductor devices, optoelectronic devices, and the like.

### BACKGROUND OF THE EMBODIMENTS

With advancements in semiconductor device technology, semiconductor devices which require accurate alignment at the sub-micron level in three dimensions are becoming increasingly common. Methods of assembling such devices can rely on various mechanical positioning features which provide an accuracy on a scale which is greater than one micron. In other methods, optical alignment schemes using a transparent wafer carrier or a front side to back side wafer alignment process can be used. These approaches can suffer from poor alignment resulting from the inherent inaccuracy of mechanical templates as well as movement of semiconductor chips in the process of bonding the chips to a substrate such as a wafer, wafer section, another semiconductor chip, or another support member.

An inexpensive method and structure which provides accurate alignment and placement techniques for bonding multiple semiconductor chips to a support member would be desirable.

### SUMMARY OF THE EMBODIMENTS

The following presents a simplified summary in order to provide a basic understanding of some aspects of one or more embodiments of the present teachings. This summary is not an extensive overview, nor is it intended to identify key or critical elements of the present teachings nor to delineate the scope of the disclosure. Rather, its primary purpose is merely to present one or more concepts in simplified form as a prelude to the detailed description presented later.

An embodiment of the present teachings can include a method used to form a semiconductor device, the method including forming at least one mechanical alignment groove within a first layer of a first device using optical photolithography, forming at least one mechanical alignment pedestal within a second layer of a second device using optical photolithography, aligning the at least one mechanical alignment groove with the at least one mechanical alignment pedestal, and placing the at least one mechanical alignment pedestal into the at least one mechanical alignment groove, such that a feature on the first device is aligned with a feature on the second device at a sub-micron tolerance.

Another embodiment of the present teachings can include a semiconductor device including a layer of a first device comprising at least one mechanical alignment groove therein, at least one mechanical alignment pedestal of a second device, wherein the mechanical alignment pedestal of the second device is within the mechanical alignment groove, and the mechanical alignment groove and the mechanical alignment pedestal align a feature on the first device with a feature on the second device at a sub-micron tolerance.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1A is a cross section along “1A-1A” of the FIG. 1B plan view of a first in-process structure which can be used to align a first device with a second device according to an exemplary embodiment of the present teachings;

FIG. 2A is a cross section along “2A-2A” of the FIG. 2B plan view of a second in-process structure according to the exemplary embodiment of the present teachings;

FIG. 3A is a cross section along “3A-3A” of the FIG. 3B plan view of a third in-process structure according to the exemplary embodiment of the present teachings;

FIG. 4A is a cross section along “4A-4A” of the FIG. 4B plan view of a fourth in-process structure according to the exemplary embodiment of the present teachings;

FIG. 5A is a cross section along “5A-5A” of the FIG. 5B plan view of a fifth in-process structure according to the exemplary embodiment of the present teachings;

FIG. 6A is a cross section along “6A-6A” of the FIG. 6B plan view of a sixth in-process structure according to the exemplary embodiment of the present teachings;

FIG. 7A is a cross, section along “7A-7A” of the FIG. 7B plan view of a seventh in-process structure according to the exemplary embodiment of the present teachings;

FIG. 8A is a cross section along “8A-8A” of the FIG. 8B plan view of a eighth in-process structure according to the exemplary embodiment of the present teachings;

FIG. 9A is a cross section along “9A-9A” of the FIG. 9B plan view of a ninth in-process structure according to the exemplary embodiment of the present teachings;

FIG. 10A is a cross section along “10A-10A” of the FIG. 10B plan view of a tenth in-process structure according to the exemplary embodiment of the present teachings;

FIG. 11 is an exploded perspective view depicting a semiconductor assembly according to the exemplary embodiment of the present teachings;

FIGS. 12 and 13 are cross sections depicting another embodiment of the present teachings to align a first device to a second device;

FIGS. 14 and 15 are cross sections depicting another embodiment of the present teachings; and

FIGS. 16 and 17 are cross sections depicting another embodiment of the present teachings.

It should be noted that some details of the FIGS. may have been simplified and drawn to facilitate understanding of the present teachings rather than to maintain strict structural accuracy, detail, and scale.

### DESCRIPTION OF THE EMBODIMENTS

Reference will now be made in detail to the present embodiments of the present teachings, examples of which are illustrated in the accompanying drawings. Wherever possible, the same reference numbers will be used throughout the drawings to refer to the same or like parts.

The present teachings are directed to self-alignment methods and structures for locating and bonding one or more semiconductor chips upon a semiconductor wafer, a portion of a semiconductor wafer, another semiconductor chip, or other support member. The self-alignment technique can provide good alignment precision and accuracy, good reliability, improved manufacturing yields, and decreased device rework at a relatively low cost. The method can employ semiconductor wafer processing techniques such as optical photolithography, dry and/or wet etching, and thin film deposition to provide matching alignment features (i.e., pedestals and grooves) on the support member and one or more semiconductor chips. Metal pads and solder bumps can be deposited on the support member, the one or more semiconductor chips, or both. The semiconductor chip can be mounted onto the support member using flip chip bonding, where the matching pedestals and grooves provide self-alignment of the chip to the support member. Thermal bonding of metal solder can be used to electrically couple the one or more semiconductor chips to the support member. Multiple chips can be similarly mounted to the support member to provide a multi-chip module. The method can use semiconductor wafer processing techniques to achieve sub-micron accuracy for mechanical alignment positioning features. Such techniques can result in improved alignment precision, for example more than ten times better alignment precision, than that of the prior alignment techniques. The present teachings can be used to align a variety of different devices, such as ball grid array (BGA) semiconductor devices and optical input/output (I/O) devices. Optical devices using the optical transfer of data such as optically enabled application specific integrated circuits (ASICs), fiber optic devices, photonic integrated circuits (PIC), etc., require precise alignment to ensure the proper transfer of electrical and/or optical signals.

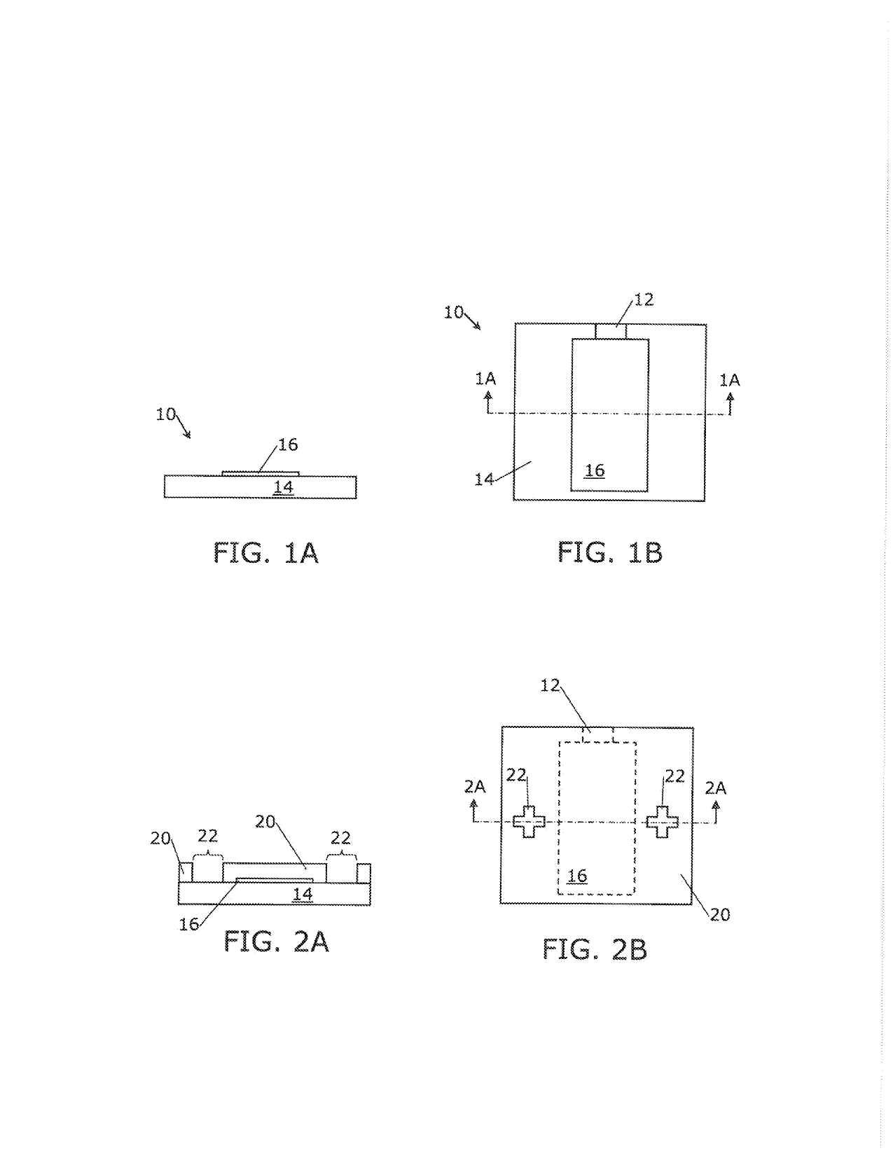

An embodiment of the present teachings is depicted in FIGS. 1-11. FIG. 1A is a cross section of a semiconductor device along 1A-1A of the FIG. 1B plan view. It will be noted that in FIGS. 1-10, an “A” drawing will generally be a cross section at the depicted location of the “B” drawing plan view. In this embodiment, the semiconductor device 10 can be an optical I/O device having an optical I/O connector 12 which is to be precisely aligned with an I/O connector of another device as described below. The semiconductor device 10 can further include a semiconductor substrate 14 and a conductive pad 16, which can be metal.

Next, a patterned mask layer 20 can formed over the surface of the semiconductor device 10 as depicted in FIGS. 2A and 2B. The patterned mask layer 20 can be, for example, a photosensitive layer such as photoresist which has been patterned using optical photolithography. Photolithography processes can accurately place features such as one or more patterned openings 22 relative to the semiconductor substrate 14. The openings 22 can include a shape which will facilitate accurate placement of the semiconductor device 10 in the X-direction and the Y-direction onto a support member as described below. In this embodiment, each opening 22 includes a “+” shape, but it will be understood that other patterns, such as circles, ovals, zigzag, etc., can be used. Generally, more than one pattern opening 22 can be used to ensure most accurate alignment. For simplicity of depiction, the pattern openings 22 are horizontally aligned in the FIGS., but it will be understood that the patterns can be placed in the corners of the FIG. 2B device, or at other device locations.

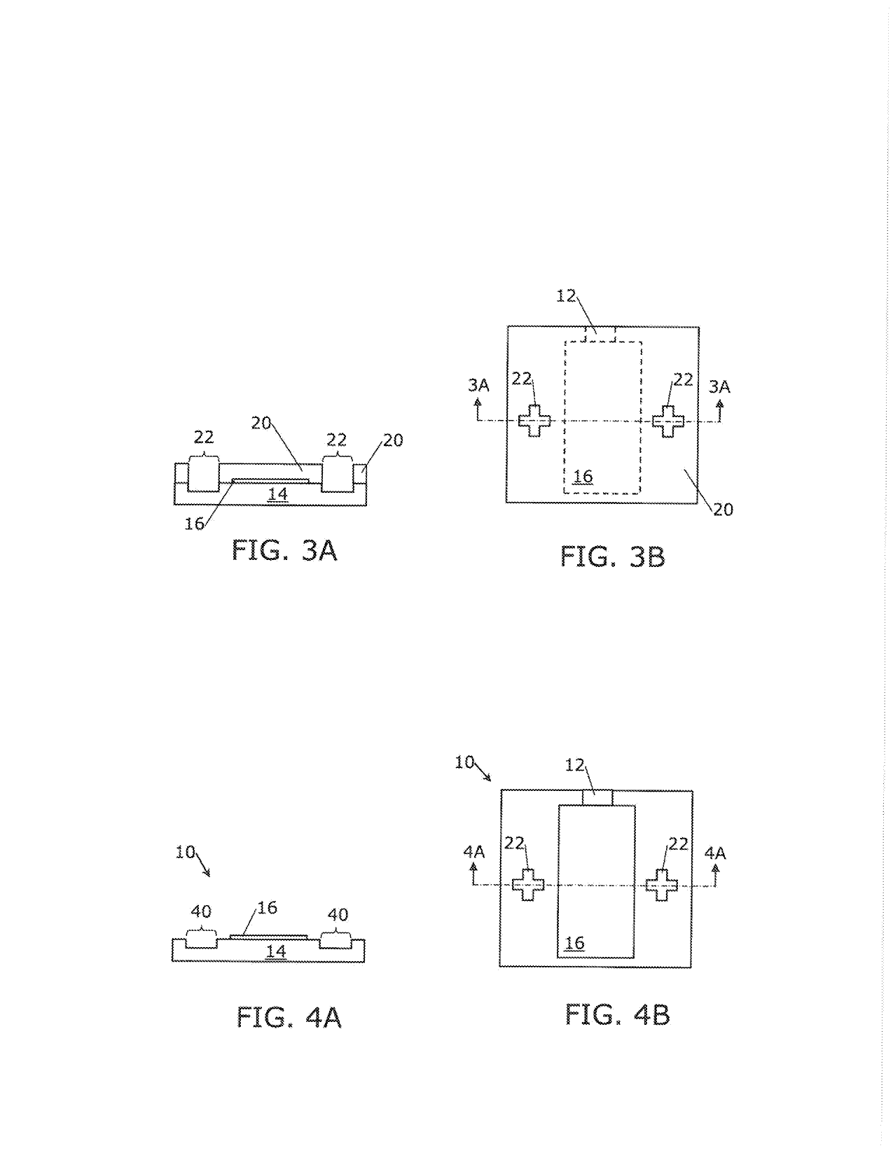

After forming the FIG. 2 device, the semiconductor substrate 14 can be etched using a wet or dry etch to transfer the pattern of mask 20 into the semiconductor substrate 14, and to result in a device similar to that depicted in FIGS. 3A and 3B. Subsequently, the patterned mask layer 20 is removed to result in the structure of FIGS. 4A and 4B. The device can include an etched alignment pattern which provides mechanical alignment grooves 40 within the semiconductor substrate 14. The mechanical alignment grooves 40 can be etched to a depth of sub-micron to through-wafer. The depth will depend, for example, on the thickness of the semiconductor substrate 14.

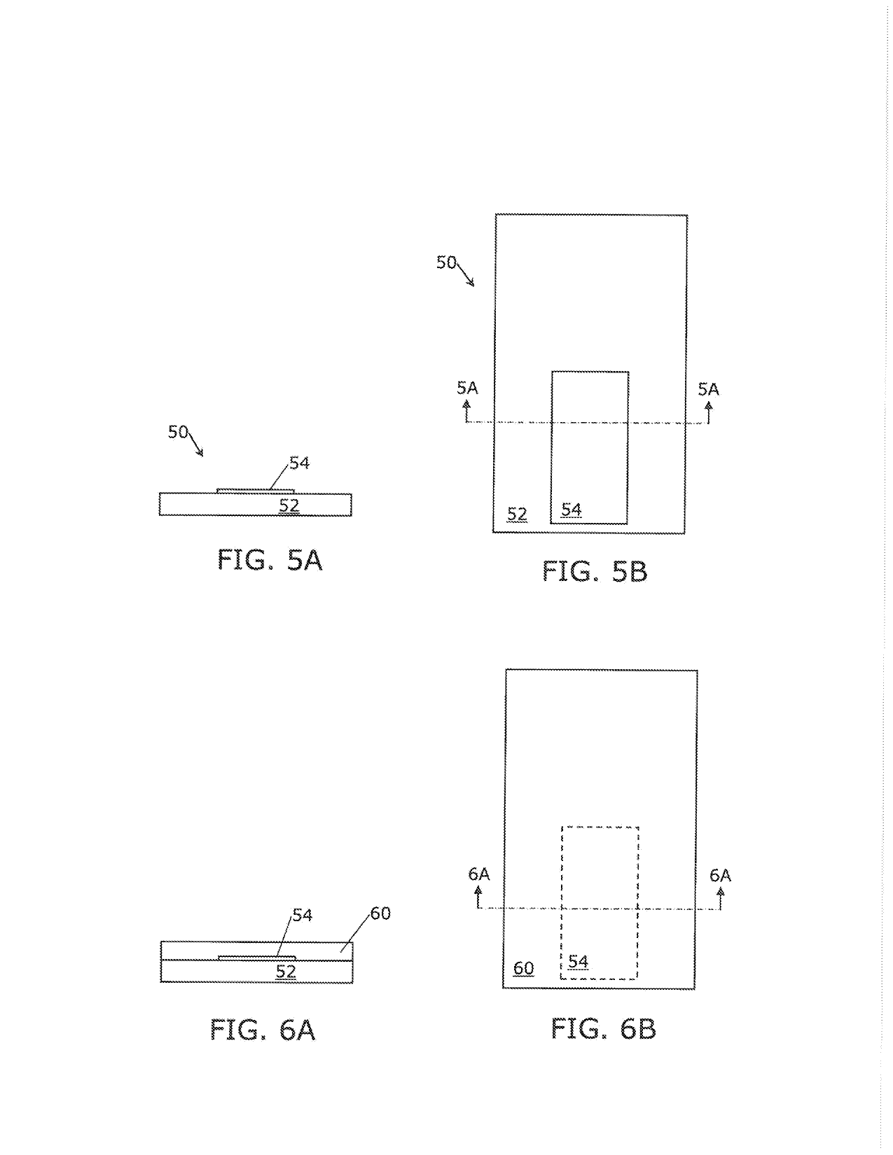

FIGS. 5A and 5B depict a support member 50 to which the semiconductor device 10 will be mounted. Prior to attaching the semiconductor device 10, mechanical alignment pedestals can be formed on the support member 50, for example using optical photolithography. The mechanical alignment pedestals match the mechanical alignment grooves 40 of the semiconductor device 10. Optical photolithography is a precise method of locating the alignment pedestals, and the support member 50 and semiconductor device 10 can be aligned to each other with high precision. The support member 50 can include a substrate 52 and a conductive pad 54. The substrate 52 can be a semiconductor wafer, a portion of a semiconductor wafer, a printed circuit board, a ceramic substrate, etc.

As depicted in FIGS. 6A and 6B, a layer of pedestal material 60 is formed over the surface of the support member 50. The pedestal material 60 can be either an electrical insulator (i.e., a dielectric) or an electrical conductor, for example metal, doped semiconductor films, etc., formed using deposition techniques such as sputtering, evaporation, chemical vapor deposition, physical vapor deposition, etc. The pedestal material 60 will typically include a material which can be etched selective to the substrate 52 and other layers overlying the substrate 52, such as the conductive pad 54. The pedestal layer 60 can have a thickness of sub-micron to through-wafer. The thickness will depend on the depth of the mechanical alignment grooves 40, as well as the thickness of any other layers overlying the semiconductor device substrate 10 and the support member 50. The pedestal layer 60 can be formed as a blanket layer as depicted using a blanket deposition process, or it can be formed as a local layer using, for example, screen printing at a target area.

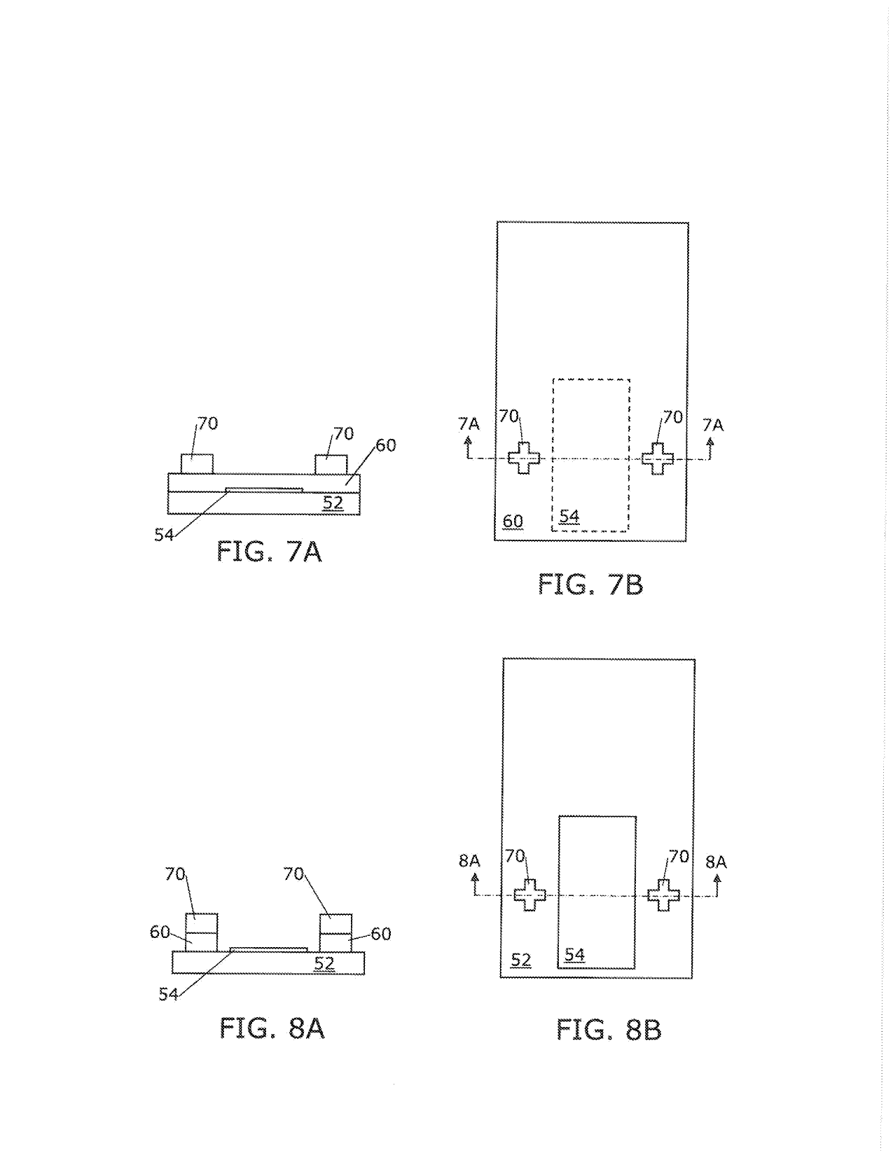

Next, a patterned mask layer 70 is formed over the pedestal layer 60 as depicted in FIGS. 7A and 7B. The patterned mask layer 70 can be a photoresist layer patterned using optical photolithography.

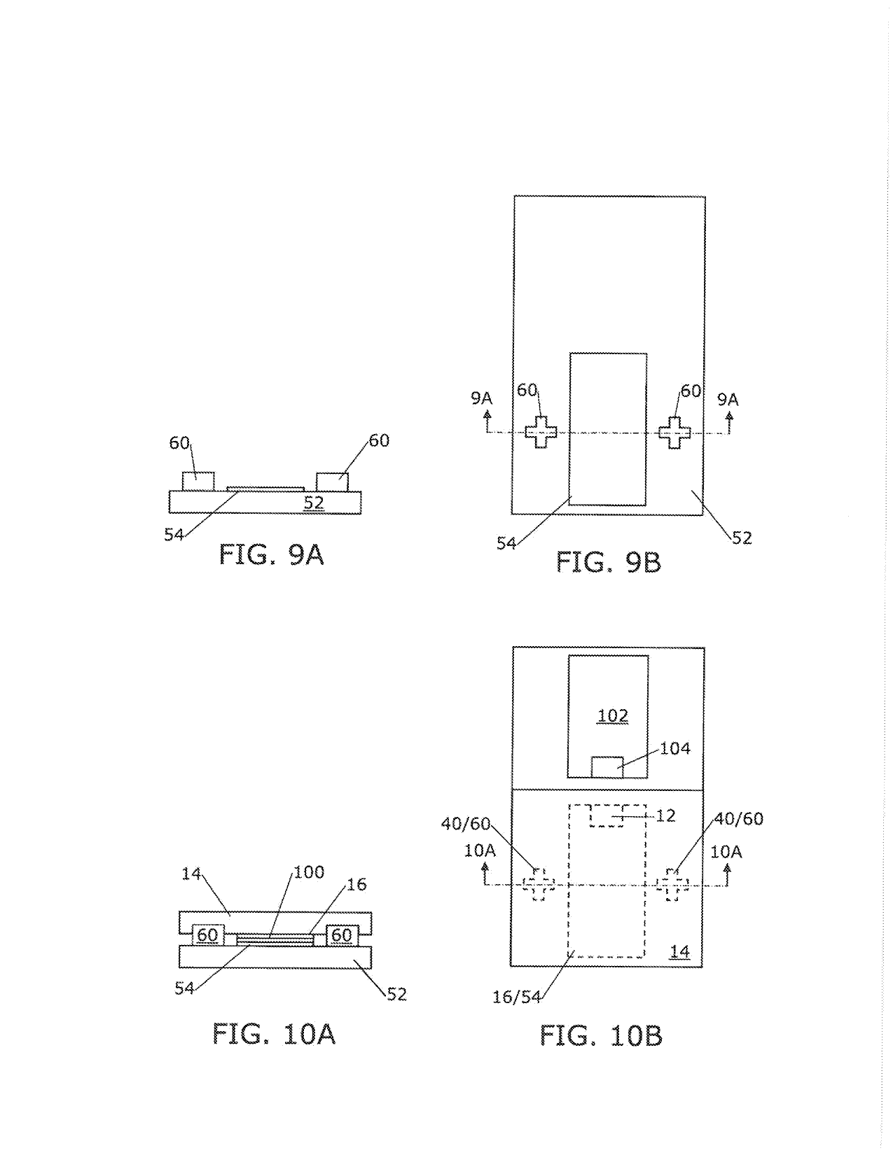

Subsequently, the pedestal layer 60 is etched using the patterned mask layer 70 as a pattern to transfer the pattern into the pedestal layer 60, and to result in a structure similar to that depicted in FIGS. 8A and 8B. The patterned mask layer 70 is then removed using known techniques as depicted in FIGS. 9A and 9B to result in the mechanical alignment pedestals 60.

After forming the mechanical alignment grooves 40 on the semiconductor device 10 and the mechanical alignment pedestals 60 on the support member 50, additional processing on either device can be performed prior to attaching the two devices 10, 50. This can include the formation of a conductive layer 100, such as a metal solder or a conductive paste, as depicted in FIGS. 10A and 10B on either or both of the conductive pads 16, 53. Additional processing can also include the attachment of an optoelectronic I/O device 102 having an optical I/O connector 104 to the substrate 52 of the support member 50. After processing, a completed structure such as that depicted in FIG. 10 can remain.

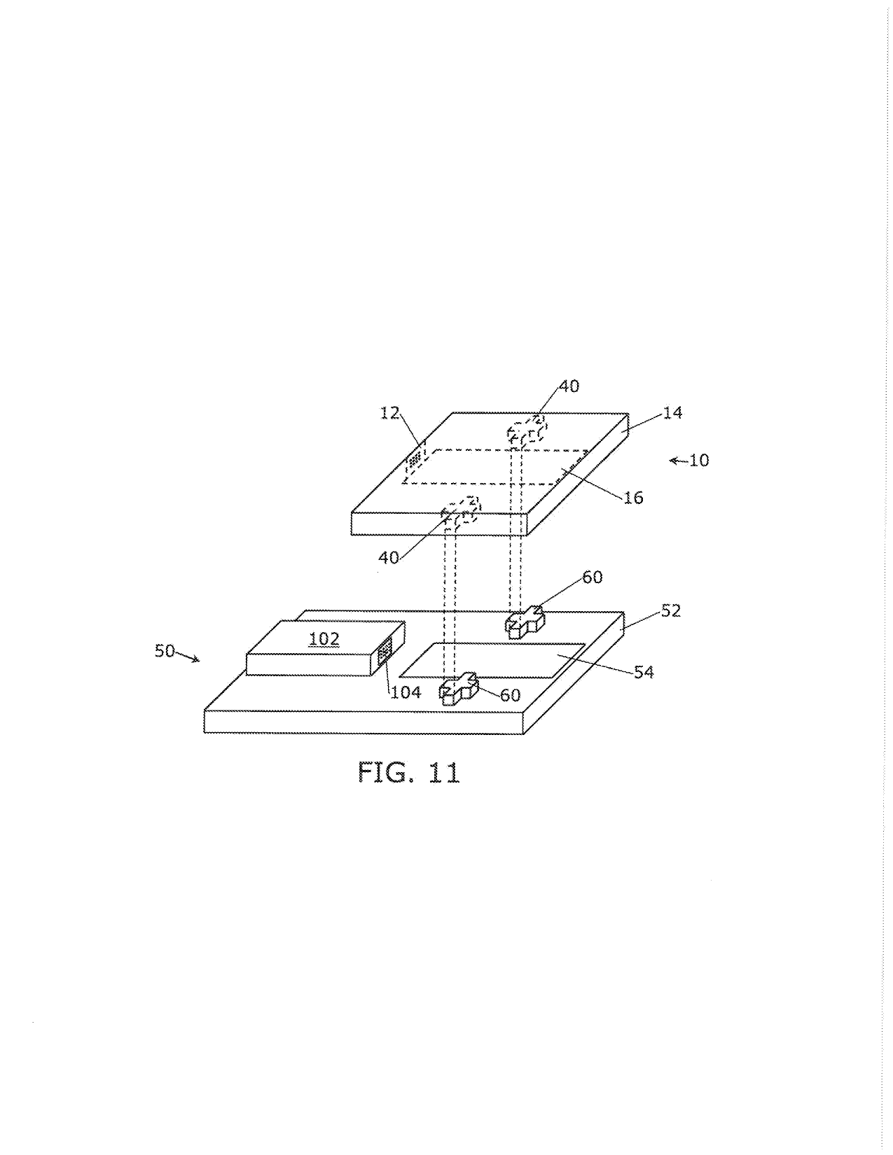

FIG. 11 is an exploded perspective view representing the alignment and flip-chip attachment of the semiconductor device 10 to the support member 50. The mechanical alignment pedestals 60 are aligned to, and placed within, the mechanical alignment grooves 40 to align devices 10, 50 to a sub-micron tolerance. The formation of the mechanical alignment grooves 40 and the mechanical alignment pedestals 60 using optical photolithographic processing results in precisely placed and sized pedestals 60 and grooves 40. The pedestals 60 and grooves 40 are formed as matching structures, and result in precise alignment of optical I/O connector 12 to optical I/O connector 104. The placement and alignment of the pedestals 60 and grooves 40, and the alignment of I/O connector 12 to I/O connector 104, can provide an alignment tolerance of less than one micron. Attachment of the conductive pads 16, 54 can be performed by thermosonic bonding, solder reflow, or curing of a conductive adhesive such as a solder paste 100.

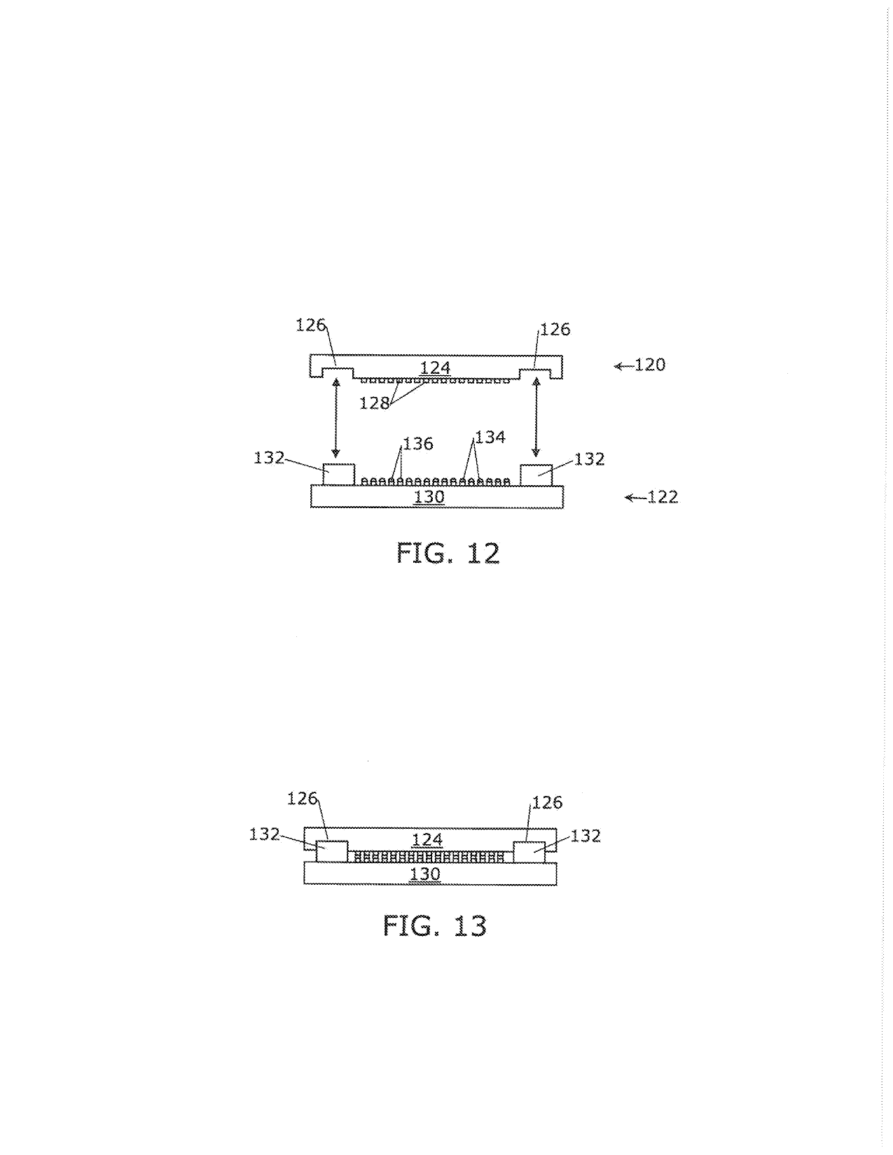

Various embodiments of the present teachings are contemplated. FIG. 12, for example, depicts a semiconductor device 120 which is to be attached to a support member 122 using ball grid array (BGA) processing. The semiconductor device 120 can include a semiconductor substrate 124 having one or more mechanical alignment grooves 126 formed according to the techniques described above, and can include a plurality of conductive pads 128, for example bond pads, attached to semiconductor circuitry (not individually depicted for simplicity). The support member 122 can include a substrate, one or more mechanical alignment pedestals 132, a plurality of conductive BGA posts 134, with a surface of each post 134 having a conductor 136 such as solder or conductive paste. It will be understood that the semiconductor device 120 and/or the support member 122 can have additional structures and circuitry which is not described herein or depicted for simplicity.

In this embodiment, the mechanical alignment grooves 126 and the mechanical alignment pedestals 132 are formed such that they align to properly and accurately align the bond pads 128 to the posts 134. Using optical photolithography, the alignment can be accurate at the sub-micron level. The mechanical alignment pedestals 132 are placed into the mechanical alignment grooves 126 such that each bond pad 128 contacts the conductor 136 on the surface of a BGA post 134. The conductor is reflowed using heat then cooled (if solder conductor is used) or otherwise cured (if conductive paste is used) to physically and conductively attach the semiconductor device 120 to the support member 122 as depicted in FIG. 13.

While the embodiments of FIGS. 1-13 depict the formation of the mechanical alignment pedestals on the support member and the mechanical alignment grooves on the semiconductor device, it will be understood that the location of the grooves and pedestals can be reversed. Additionally, it is contemplated that both grooves and pedestals can be formed on both devices, with the grooves on one device matching the pedestals on the other device.

Additionally, the embodiments described above depict the use of anisotropic (vertical) etches which form mechanical alignment grooves and mechanical alignment pedestals having substantially vertical sidewalls (i.e., sidewalls having an angle of about 90°). It will be understood that isotropic etches can be used to etch the mechanical alignment grooves, or the mechanical alignment pedestals, or both. Using an isotropic etch to form the grooves and/or pedestals forms grooves and/or pedestals having a sloped profile (i.e., sidewalls having an angle of between about 30° and about 60°, for example about 45°). A sloped profile can allow for some horizontal misalignment of the devices relative to each other during attachment of the semiconductor device to the support member, with the resulting device having no decrease in alignment tolerance.

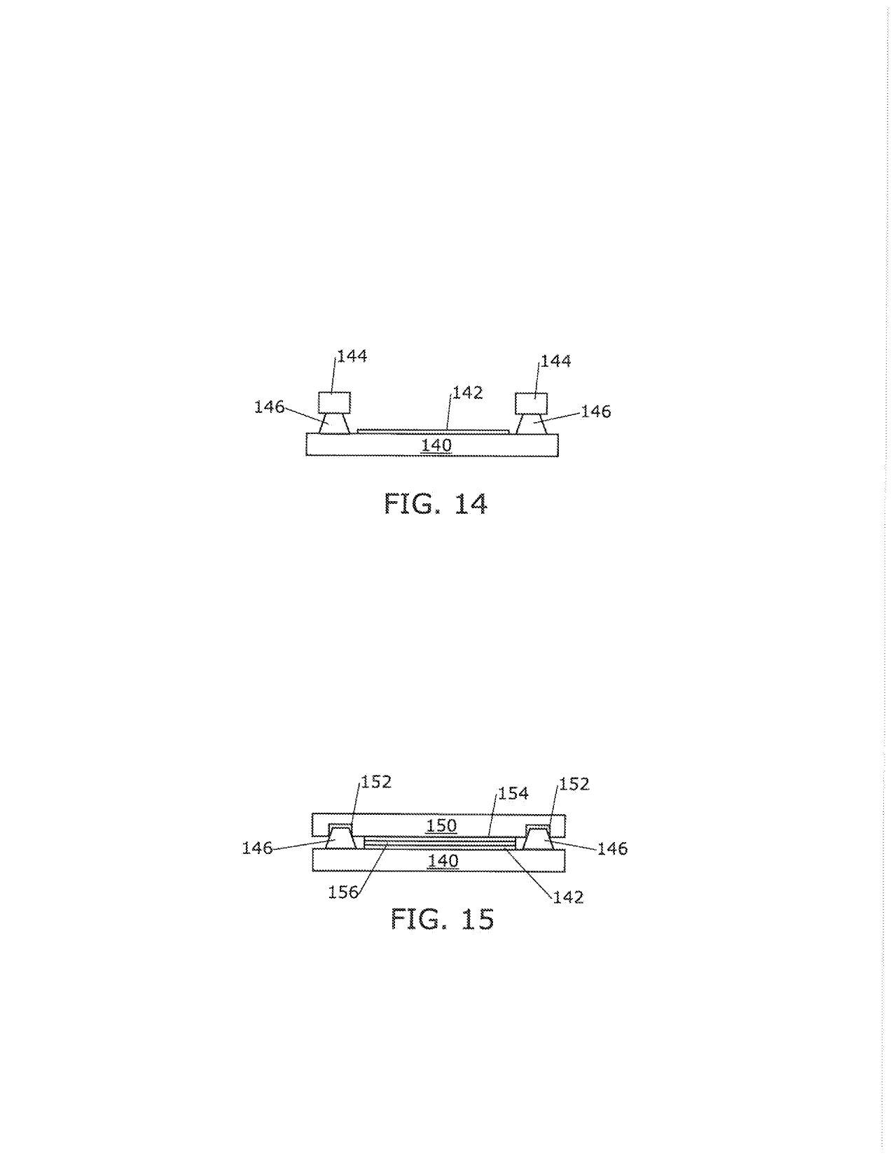

FIG. 14, for example, depicts a semiconductor device having a substrate 140 and conductive pad 142 formed on the substrate 140, and a patterned photoresist layer 144 which is used to etch pedestals 146. An isotropic etch is used such that the photoresist 144 is undercut during the etch to result in pedestals 146 which have a sloped profile. During alignment of sloped mechanical alignment pedestals 146 to mechanical alignment grooves, the pedestals can be laterally misaligned with the grooves. As the misaligned semiconductor device and support member are brought together, the sloped pedestals 146 force the devices into correct alignment. FIG. 15 depicts the FIG. 14 device attached to a support member 150 having mechanical alignment grooves 152. A conductive pad 154 on the support member 150 is attached to the conductive pad 142 using a conductor 154 such as solder or conductive paste.

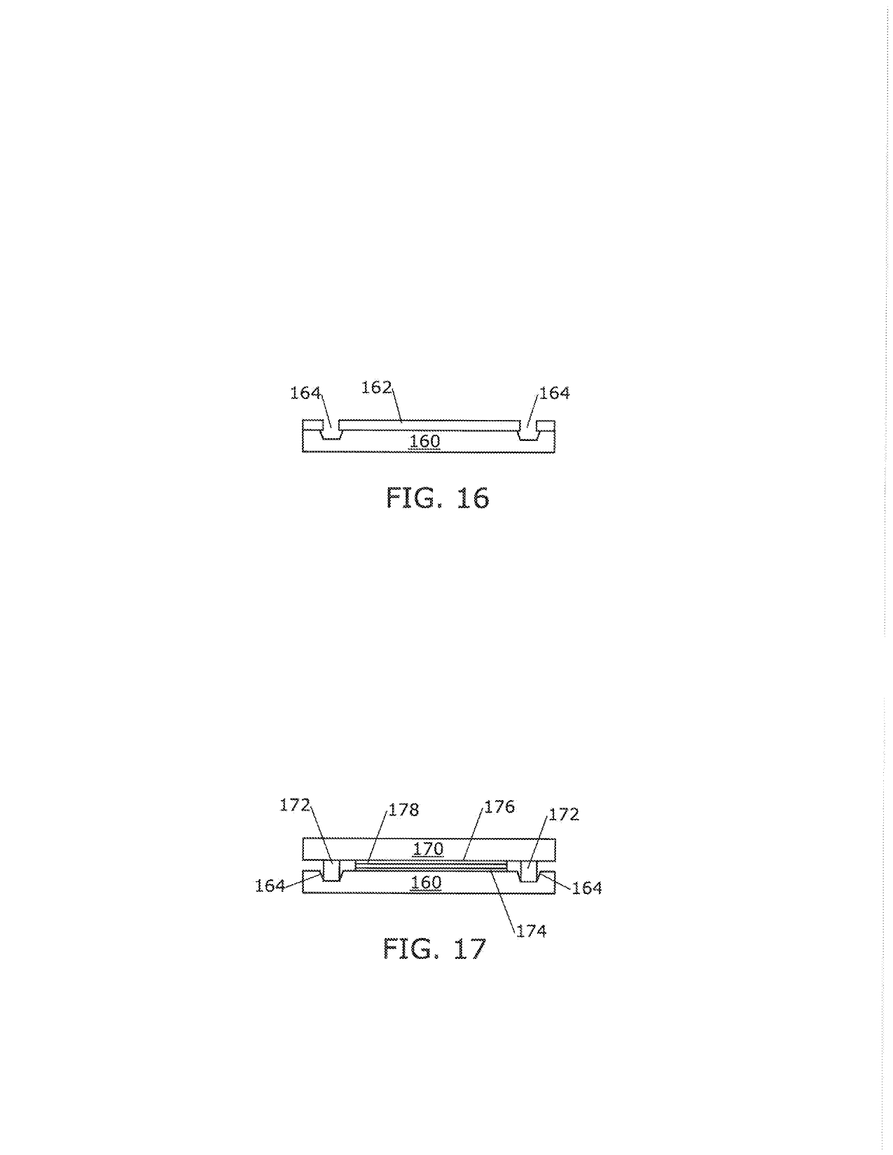

FIG. 16 depicts a substrate 160. A patterned photoresist 162 has been undercut using an isotropic etch to form mechanical alignment grooves 164 having a sloped profile. The sloped profile of the mechanical alignment grooves 164 can allow for some lateral misalignment during attachment to another substrate. The sloped sidewall will pull the devices into alignment as they are moved toward each other, much the same way as the sloped mechanical alignment pedestals described above. FIG. 17 depicts the FIG. 16 substrate 160 attached to a support member 170 having mechanical alignment pedestals 172. The mechanical alignment grooves 164 and mechanical alignment pedestals 172 align a conductive pad 174 on the substrate 160 to a conductive pad 176 on the support member 170. Conductive pads 174, 176 are electrically coupled using a conductor 178.

In another embodiment, both the mechanical alignment grooves and the mechanical alignment pedestals can have sloped profiles. This may allow for increased lateral misalignment of the devices during assembly, with a completed multi-chip device having properly aligned components.

While the mechanical alignment grooves have been described as being formed within a layer such as a semiconductor substrate of a semiconductor device, it will be understood that the grooves can be formed within a layer overlying a semiconductor substrate, such as a conductor or dielectric layer, or within a layer such as a ceramic substrate or a printed circuit board. Similarly, the mechanical alignment pedestals can be form within or over a semiconductor substrate, a ceramic layer, a printed circuit board, a dielectric layer, or a conductive layer.

Embodiments of the present teachings therefore provide a self-alignment mechanism for multiple chip assembly. The alignment accuracy can be in sub-micron scale. The mechanical alignment features can be formed using semiconductor wafer processing techniques, and can be manufactured using high volume and high accuracy production techniques. Embodiments can include the alignment of microelectronic components such as semiconductor chips, microelectronic chips, and optoelectronic chips, as well as combinations thereof. In an embodiment, use of the present teachings can align an electrical connector on the first device with an electrical connector on the second device, and/or an optical connector on the first device with an optical connector on the second device. In another embodiment, use of the present teachings can physically align a first device to a second device, without any electrical connection between the first device and the second device in the completed assembly.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

To the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method used to form a semiconductor device, comprising:
forming at least one mechanical alignment groove within a first layer of a first device using optical photolithography;
forming at least one mechanical alignment pedestal within a second layer of a second device using optical photolithography;
aligning the at least one mechanical alignment groove with the at least one mechanical alignment pedestal; and
placing the at least one mechanical alignment pedestal into the at least one mechanical alignment groove, such that a feature on the first device is aligned with a feature on the second device at a sub-micron tolerance.

2. The method of claim further comprising:
the feature on the first device is an optical input/output (I/O) connector of a first optoelectronic I/O device;
the feature on the second device is an optic I/O connector of a second optoelectronic I/O device; and
placing the at least one mechanical alignment pedestal into the at least one mechanical alignment groove aligns the optical I/O connecter of the first optoelectronic I/O device with the optical I/O connector of the second optoelectronic I/O device.

3. The method of claim 1, further comprising:
the feature on the first device is a plurality of bond pads;
the feature on the second device is a plurality of conductive posts;
placing the at least one mechanical alignment pedestal into the at least one mechanical alignment groove aligns the plurality of bond pads with the plurality of posts.

4. The method of claim 1, further comprising:
forming a first patterned photoresist layer over a blanket first layer;
etching the blanket first layer using the first patterned photoresist layer as a pattern to form the at least one mechanical alignment groove within the first layer of the first device;
forming a second patterned photoresist layer over a blanket second layer;
etching the blanket second layer using the second patterned photoresist layer as a pattern to form the at least one mechanical alignment pedestal within the second layer of the second device; and
removing the first patterned photoresist layer and the second patterned photoresist layer prior to aligning the at least one mechanical alignment groove with the at least one mechanical alignment pedestal.

5. The method of claim 4, further comprising:
etching at least one of the blanket first layer and the blanket second layer with an anisotropic etch to form at least one of substantially vertical mechanical alignment groove sidewalls and substantially vertical mechanical alignment pedestal sidewalls.

6. The method of claim 4, further comprising:
etching the at least one of the blanket first layer and the blanket second layer with an isotropic etch to form at least one of sloped mechanical alignment groove sidewalls and sloped mechanical alignment pedestal sidewalls, wherein a slope of the sloped sidewall is between about 30° and about 60°.

7. The method of claim 1, further comprising:
electrically coupling the first device to the second device using flip-chip bonding.

8. The method of claim 1, further comprising:
physically attaching the first device to the second device to for a multi-chip module, wherein no electrical connection is made between the first device and the second device.

9. The method of claim 1, further comprising:
forming the at least one mechanical alignment groove within the first layer, wherein the first layer is an electrical insulator; and
forming the at least one mechanical alignment groove within the second layer, wherein the second layer is an electrical insulator.

10. A semiconductor device, comprising:
a first device comprising:
a first surface and a second surface that is opposite to the first surface; and
at least one mechanical alignment groove within the first surface of the first device;
a second device comprising:
a first surface and a second surface that is opposite to the first surface; and
at least one mechanical alignment pedestal extending away from the first surface of the second device, wherein the mechanical alignment pedestal of the second device does not extend into the first surface of the second device or into the second surface of the second device and is within the mechanical alignment groove; and
the mechanical alignment groove and the mechanical alignment pedestal align a feature on the first surface of the first device with a feature on the first surface of the second device at a sub-micron tolerance.

11. The semiconductor device of claim 10, further comprising:
the feature on the first surface of the first device is an optical input/output (I/O) connector of a first optoelectronic I/O device;
the feature on the first surface of the second device is an optical I/O connector of a second optoelectronic I/O device; and
the at least one mechanical alignment pedestal and the at least one mechanical alignment groove aligns the optical I/O connecter of the first optoelectronic I/O device with the optical I/O connector of the second optoelectronic I/O device.

12. The semiconductor device of claim 10, further comprising:
the feature on the first surface of the first device is a plurality of bond pads;
the feature on the first surface of the second device is a plurality of conductive posts;
the at least one mechanical alignment pedestal and the at least one mechanical alignment groove aligns the plurality of bond pads with the plurality of posts.

13. The semiconductor device of claim 10, further comprising:
at least one of the mechanical alignment groove and the mechanical alignment pedestal comprises at least one sidewall forming an angle of about 90° with at least one of the first surface of the first device and the first surface of the second device.

14. The semiconductor device of claim 10, further comprising:
at least one of the mechanical alignment groove and the mechanical alignment pedestal sidewalls has a sloped sidewall, wherein a slope of the sloped sidewall is between about 30° and about 60°.

15. The method of claim 10, further comprising:
the first surface of the first device is physically attached to the first surface of the second device to form a multi-chip module, wherein no electrical connection is made between the first device and the second device.

16. The semiconductor device of claim 10, further comprising:
the mechanical alignment groove is formed within an electrical insulator layer of the first device; and
the mechanical alignment pedestal is an electrical insulator.

17. The semiconductor device of claim 10, wherein;
the mechanical alignment groove, in plan view, comprises a “+” shape: and
the mechanical alignment pedestal, in plan view, comprises a “+” shape.

18. The semiconductor device of claim 10, wherein:
the mechanical alignment groove, in plan view, comprises one of an oval shape, and a zigzag shape; and
the mechanical alignment pedestal, in plan view, comprises the one of the oval shape and the zigzag shape.

19. The semiconductor device of claim 10, wherein the first device is flip-chip bonded to the second device.
